(19) United States
(12) Patent Application Publication
(10) Pub. No.: US 2024/0322077 A1
(43) Pub. Date: Sep. 26, 2024

(54) DISPLAY APPARATUS

(71) Applicant: Samsung Display Co., Ltd., Yongin-si (KR)

(72) Inventors: Hyuneok Shin, Yongin-si (KR); Sungjoo Kwon, Yongin-si (KR); Juhyun Lee, Yongin-si (KR); Yangho Jung, Yongin-si (KR); Yungbin Chung, Yongin-si (KR); Yugwang Jeong, Yongin-si (KR)

(73) Assignee: Samsung Display Co., Ltd., Yongin-si (KR)

(21) Appl. No.: 18/602,289

(22) Filed: Mar. 12, 2024

(30) Foreign Application Priority Data
Mar. 24, 2023 (KR) 10-2023-0039139
Apr. 6, 2023 (KR) 10-2023-0045399

(51) Int. Cl. H01L 33/24; H01L 25/075

(52) U.S. Cl. CPC H01L 33/24; H01L 25/0753

(57) ABSTRACT

A display apparatus includes a display panel including a display area, multiple first partitions disposed on the display panel in the display area, and a first auxiliary layer arranged on at least a portion of outer surfaces of the first partitions and including an opening arranged between adjacent first partitions.

### CROSS-REFERENCE TO RELATED APPLICATION(S)

This application claims priority to and benefits of Korean Patent Application Nos. 10-2023-0039139 filed on Mar. 24, 2023, and 10-2023-0045399 filed on Apr. 6, 2023, in the Korean Intellectual Property Office (KIPO), under 35 U.S.C. § 119, the entire contents of which are incorporated herein by reference.

### BACKGROUND

### 1. Technical Field

Embodiments relate to a display apparatus only filtering emitted light in a certain direction generated in a display panel.

### 2. Description of the Related Art

Display apparatuses are apparatuses that receive information regarding images and display images. Emitted light generated from display panels included in the display apparatuses may be emitted in various directions. Therefore, there is a need for a viewing-angle control technology that transmits light emitted in a vertical direction with respect to a display panel.

### SUMMARY

Emitted light generated in a display panel may be emitted in various directions. Embodiments provide a display apparatus that only filters, from among emitted light, vertical light emitted in a vertical direction with respect to a display panel. However, technical problems to be solved by the disclosure are not limited thereto.

Additional aspects will be set forth in part in the description which follows and, in part, will be apparent from the description, or may be learned by practice of the presented embodiments of the disclosure.

According to an embodiment, a display apparatus may include a display panel including a display area, a plurality of first partitions disposed on the display panel in the display area, and a first auxiliary arranged on at least a portion of outer surfaces of the plurality of first partitions and including an opening arranged between adjacent ones of the plurality of first partitions.

A height of at least one of the plurality of first partitions measured from a top surface of the display panel to a top surface of the at least one of the plurality of first partitions may be greater than a distance between adjacent ones of the plurality of first partitions.

At least one of the plurality of first partitions may include an inorganic material.

The at least one of the plurality of first partitions may include molybdenum tantalum oxide (MoTaOₓ, MTO).

The first auxiliary layer may cover the plurality of first partitions and the display panel.

The first auxiliary layer may include a transparent material.

In an embodiment, the display apparatus may further include a first stable layer at least partially arranged in the opening of the first auxiliary layer.

The first stable layer may include a transparent material.

In an embodiment, the display apparatus may further include a second partition on and overlapping at least one of the plurality of first partitions in a plan view.

A height of the second partition measured from a top surface of the display panel to a top surface of the second partition may be greater than a distance between adjacent ones of the plurality of first partitions.

The at least one of the plurality of first partitions may directly contact the second partition.

The second partition may include an organic material.

In an embodiment, the display apparatus may further include a plurality of second partitions, and a second auxiliary layer arranged on at least a portion of outer surfaces of the plurality of second partitions and including an opening arranged between adjacent ones of the plurality of second partitions.

In an embodiment, the display apparatus may further include a third partition arranged on the second partition and overlapping the second partition in a plan view.

A height of the third partition measured from a top surface of the display panel to the top surface of the third partition may be greater than a distance between adjacent ones of the plurality of first partitions.

The second partition may directly contact the third partition.

The third partition may include an inorganic material.

According to an embodiment, a display apparatus may include a display panel including a display area including a plurality of subpixels and a non-display area, a plurality of first partitions disposed on the display panel in the display area and overlapping at least one of the plurality of subpixels in a plan view, and a first auxiliary layer arranged on at least a portion of outer surfaces of the plurality of first partitions and including an opening arranged between adjacent ones of the plurality of first partitions.

The first auxiliary layer may cover at least one of the plurality of first partitions.

The first auxiliary layer may be arranged on side surfaces of the plurality of first partitions.

In an embodiment, the display apparatus may further include a first stable layer at least partially arranged in the opening.

In an embodiment, the display apparatus may further include a second partition arranged on and overlapping at least one of the plurality of first partitions in a plan view.

The at least one of the plurality of first partitions may directly contact the second partition.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a top-plan view schematically illustrating a display apparatus according to an embodiment of the disclosure;

FIG. 2 is a schematic cross-sectional view taken along line II-II′ shown in FIG. 1;

FIG. 3 is a schematic cross-sectional view of a portion of a display apparatus according to an embodiment of the disclosure;

FIG. 4 is a top-plan view schematically illustrating a portion of a display apparatus according to an embodiment of the disclosure;

FIGS. 5A to 5C are each a schematic cross-sectional view illustrating a state of a partition structure according to a manufacturing process thereof, according to an embodiment of the disclosure;

FIG. 6 is a schematic cross-sectional view of a partition structure according to an embodiment of the disclosure;

FIG. 7 is a schematic cross-sectional view of a partition structure according to an embodiment of the disclosure;

FIG. 8 is a schematic cross-sectional view of a partition structure according to an embodiment of the disclosure;

FIG. 9 is a schematic cross-sectional view of a partition structure according to an embodiment of the disclosure;

FIG. 10 is a schematic cross-sectional view of a partition structure according to an embodiment of the disclosure;

FIG. 11 is a schematic cross-sectional view of a partition structure according to an embodiment of the disclosure;

FIG. 12 is a schematic cross-sectional view of a partition structure according to an embodiment of the disclosure; and

FIG. 13 is a schematic cross-sectional view of a partition structure according to an embodiment of the disclosure.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

It is noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

It will be further understood that the terms “comprise,” “comprising,” “include,” “including,” “have,” “having,” and the like, when used herein, specify the presence of stated features and/or elements, but do not preclude the presence or addition.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the drawings, the sizes of elements may be exaggerated or reduced for convenience of description. For example, since the size and thickness of each element is arbitrarily shown in the drawings for convenience of description, the disclosure is not necessarily limited to those illustrated.

When some embodiments may be differently implemented, a particular process sequence may be performed differently from a sequence described. For example, two processes described in succession may be performed substantially simultaneously, or may be performed in an order opposite to an order described.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

An x-axis, a y-axis, and a z-axis are not limited to three axes on an orthogonal coordinate system, and may be interpreted as a wide meaning including the same. For example, the x-axis, y-axis, and z-axis may be orthogonal to one another, but may also refer to different directions that are not orthogonal to one another.

Unless otherwise defined or implied herein, all terms (including technical and skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

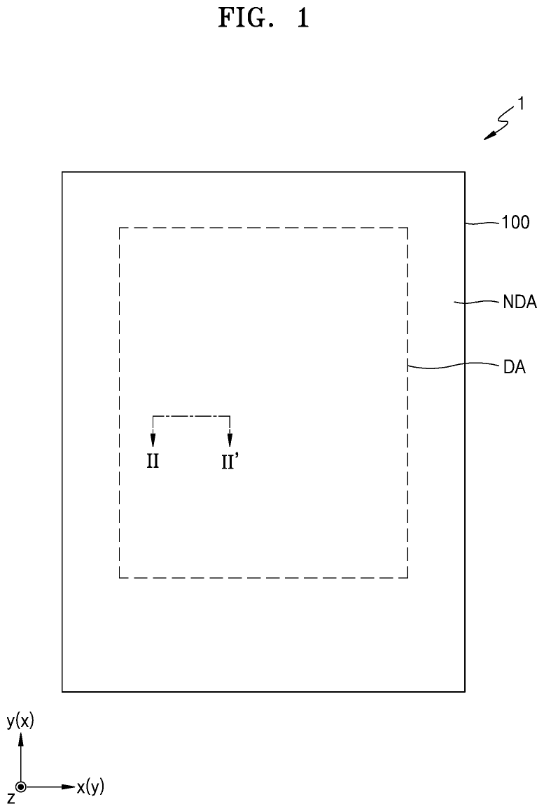

FIG. 1 is a top-plan view schematically illustrating a display apparatus 1 according to an embodiment of the disclosure.

Referring to FIG. 1, the display apparatus 1 may include a substrate 100 including a display area DA and a non-display area NDA. Subpixels including display elements such as light-emitting diodes may be arranged in the display area DA and may provide certain images. The non-display area NDA may be an area that does not provide images and may be disposed adjacent to (or may surround) the display area DA. A scan driver and a data driver that provides electrical signals to the subpixels of the display area DA and power lines that provides power such as a driving voltage and a common voltage may be arranged in the non-display area NDA.

Although FIG. 1 illustrates that a length of the display apparatus 1 in an x direction is less than a length of the display apparatus 1 in a y direction intersecting the x direction, the disclosure is not limited thereto. In another embodiment, a shape of the display apparatus 1 may be variously modified, for example, the length in the x direction may be greater than the length in the y direction.

The display apparatus 1 may be applied to various products such as mobile phones, smart phones, tablet personal computers, mobile communication terminals, electronic handbooks, electronic books, portable multimedia players, navigation systems, ultra mobile PCs, televisions, notebooks, monitors, billboard charts, Internet of things (IoT), and the like. The display apparatus 1 according to an embodiment may be also applied to wearable devices such as smart watches, watch phones, and head mounted displays (HMD). The display apparatus 1 according to an embodiment may be a center information display (CID) arranged on a dashboard or a center fascia of a vehicle, a room mirror display substituting a side mirror of a vehicle, and a display screen arranged on a back surface of a front seat as entertainment for passengers in rear seats of a vehicle.

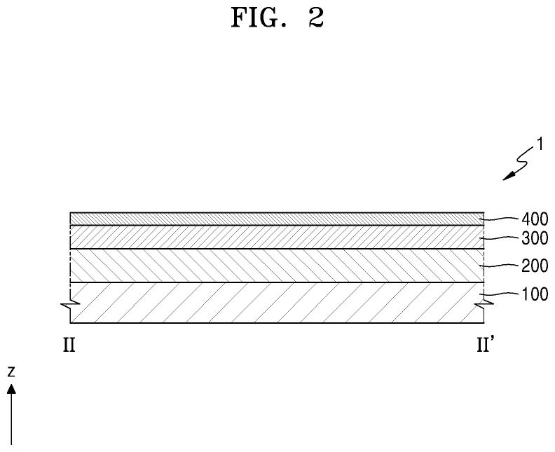

FIG. 2 is a schematic cross-sectional view taken along line II-II′ shown in FIG. 1.

Referring to FIG. 2, the display apparatus 1 may include a display element layer 200 disposed on the substrate 100. The substrate 100 may include a material such as glass, metal, or plastic, e.g., polyethylene terephthalate (PET), polyethylene naphthalate (PEN), and polyimide (PI). The display element layer 200 may include subpixels including organic light-emitting elements and may provide certain images. The display element layer 200 may be covered by an encapsulation layer 300.

The encapsulation layer 300 may be arranged to face the substrate 100 with the display element layer 200 between the encapsulation layer 300 and the substrate 100, and may protect the display element layer 200 from external moisture or oxygen. An input sensing layer 400 may be disposed on the encapsulation layer 300.

The input sensing layer 400 may include multiple touch electrodes having conductivity. For example, the input sensing layer 400 may be a capacitance type. The input sensing layer 400 may be used for output of a coordinate of a position to which an object approaches or contacts using a change in a capacitance generated in case that an object such as a user's hand approaches or contacts a surface of the input sensing layer 400.

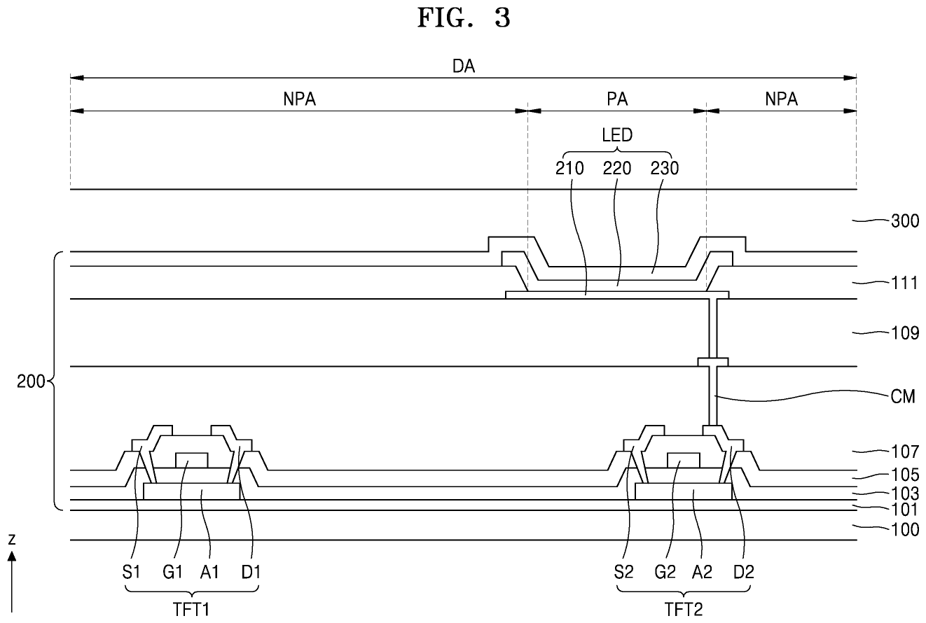

FIG. 3 is a schematic cross-sectional view of a portion of the display apparatus 1 according to an embodiment of the disclosure.

Referring to FIG. 3, the display element layer 200 may be disposed on the substrate 100, and the display element layer 200 may include light-emitting diodes LED corresponding to the subpixels arranged in the display area DA. The light-emitting diode LED may be electrically connected to a second thin-film transistor TFT2.

A first thin-film transistor TFT1 and the second thin-film transistor TFT2 may include active layers A1 and A2, gate electrodes G1 and G2 overlapping areas of the active layers A1 and A2, source electrodes S1 and S2 connected to the active layers A1 and A2, and drain electrodes D1 and D2 connected to the active layers A1 and A2.

The gate electrodes G1 and G2 may each include aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), copper (Cu), or a combination thereof, and may have a single layer structure or multiple-layer structure.

A buffer layer 101 preventing permeation of impurities may be disposed between the active layers A1 and A2 and the substrate 100. A gate insulating layer 103 may be disposed between the active layers A1 and A2 and the gate electrodes G1 and G2. An interlayer insulating layer 105 may be disposed on the gate electrodes G1 and G2. The buffer layer 101, the gate insulating layer 103, and the interlayer insulating layer 105 may each include an inorganic insulating material such as silicon oxide, silicon nitride, silicon oxynitride, aluminum oxide, aluminum nitride, titanium oxide, titanium nitride, or a combination thereof.

The source electrodes S1 and S2 and the drain electrodes D1 and D2 may be disposed on the interlayer insulating layer 105 and may be connected to the active layers A1 and A2 through contact holes formed in the interlayer insulating layer 105 and the gate insulating layer 103. The source electrodes S1 and S2 and the drain electrodes D1 and D2 may each include Al, Pt, Pd, Ag, Mg, Au, Ni, Nd, Ir, Cr, Li, Ca, Mo, Ti, W, Cu, or a combination thereof, and may have a single layer or multiple layers.

A first organic insulating layer 107 may be disposed on the first thin-film transistor TFT1 and the second thin-film transistor TFT2. The first organic insulating layer 107 may include an organic insulating material such as an acrylic material, benzocyclobutene (BCB), polyimide (PI), hexamethyldisiloxane (HMDSO), and the like.

A contact metal CM may be disposed on the first organic insulating layer 107. The contact metal CM may include Al, Cu, Ti, or a combination thereof, and may have a single layer or multiple layers.

A second organic insulating layer 109 may be between the contact metal CM and a subpixel electrode 210. The second organic insulating layer 109 may include an organic insulating material such as an acrylic material, BCB, PI, HMDSO, or the like. FIG. 3 illustrates that the second thin-film transistor TFT2 and the subpixel electrode 210 are electrically connected to each other through the contact metal CM. However, the disclosure is not limited thereto, and according to another embodiment, the contact metal CM may be omitted, and another organic insulating layer may be disposed between the second thin-film transistor TFT2 and the subpixel electrode 210. According to another embodiment, three or more organic insulating layers may be disposed between the second thin-film transistor TFT2 and the subpixel electrode 210, and the second thin-film transistor TFT2 and the subpixel electrode 210 may be electrically connected to each other through multiple contact metals.

The subpixel electrode 210 may be disposed on the second organic insulating layer 109. The subpixel electrode 210 may be formed as a (semi) transparent electrode or a reflective electrode. In case that the subpixel electrode 210 is formed as a (semi) transparent electrode, the subpixel electrode 210 may include, for example, indium tin oxide (ITO), indium zinc oxide (IZO), zinc oxide (ZnO), indium oxide (In₂O₃), indium gallium oxide (IGO), or aluminum zinc oxide (AZO?). In case that the subpixel electrode 210 is formed as a reflective electrode, a reflective film may include silver (Ag), magnesium (Mg), aluminum (Al), platinum (Pt), palladium (Pd), gold (Au), nickel (Ni), neodymium (Nd), iridium (Ir), chromium (Cr), or compounds thereof, and a film formed of ITO, IZO, ZnO, or In₂O₃ may be formed on the reflective film. In an embodiment, the subpixel electrode 210 may have a structure in which an ITO layer, an Ag layer, and an ITO layer are sequentially stacked. However, the disclosure is not limited thereto and may be variously modified, for example, the subpixel electrode 210 may be formed of various materials, and the structure thereof may include a single layer or multiple layers. The subpixel electrode 210 may be electrically connected to the contact metal CM through a contact hole formed in the second organic insulating layer 109.

A pixel defining film 111 may cover a rim area (or an edge) of the subpixel electrode 210. The pixel defining film 111 may include an opening exposing a portion of the subpixel electrode 210. The opening of the pixel defining film 111 may correspond to an area of the light-emitting diode LED, in which light is emitted, and may define a subpixel area PA.

An intermediate layer 220 may be disposed on the subpixel electrode 210. The intermediate layer 220 may include an organic emission layer (EML) including a low-molecular or high-molecular material. The intermediate layer 220 may have a structure in which a hole injection layer (HIL), a hole transport layer (HTL), the organic emission layer (EML), an electron transport layer (ETL), and/or an electron injection layer (EIL) are stacked in a single or complex structure.

A counter electrode 230 may be disposed on the intermediate layer 220. The counter electrode 230 may be formed as a (semi) transparent electrode. In case that the counter electrode 230 is formed as a (semi) transparent electrode, the counter electrode 230 may include Ag, Al, Mg, Li, Ca, Cu, LiF/Ca, LiF/Al, MgAg, CaAg, or a combination thereof, and may be formed in the form of a thin film having a thickness from several nm to tens of nm. The configuration and material of the counter electrode 230 are not limited thereto and may be variously modified.

The encapsulation layer 300 may be disposed on the counter electrode 230. The encapsulation layer 300 may include an inorganic encapsulation layer including an inorganic material and an organic encapsulation layer including an organic material. The inorganic encapsulation layer may include an inorganic insulating material such as silicon oxide, silicon nitride, and silicon oxynitride. The organic encapsulation layer may include an organic insulating material such as polyethylene terephthalate, polyethylene naphthalate, polycarbonate, and polyimide.

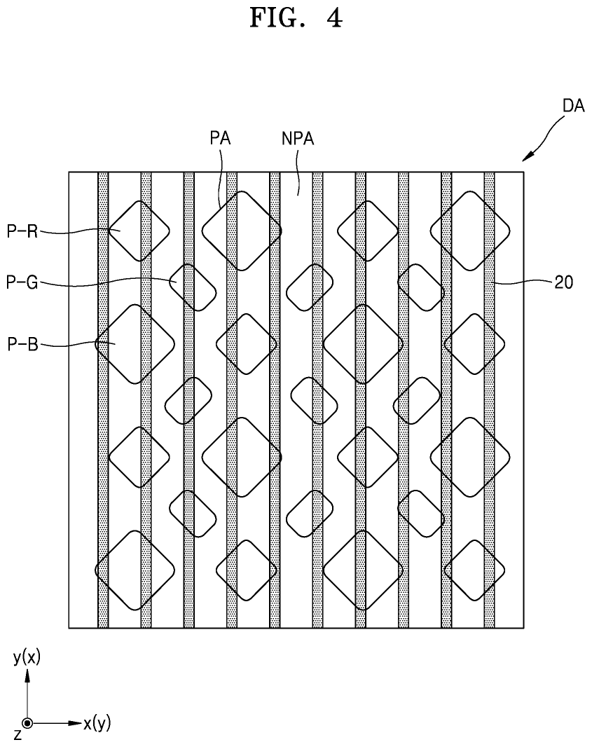

FIG. 4 is a top-plan view schematically illustrating a portion of the display apparatus 1 according to an embodiment of the disclosure.

Referring to FIG. 4, the display area DA may include subpixels that respectively emits light having different colors, for example, red subpixels P-R, green subpixels P-G, and blue subpixels P-B. Each subpixel may include the light-emitting diode described with reference to FIG. 3. The display area DA may include the subpixel area PA, in which the subpixels are arranged, and a non-subpixel area NPA surrounding the subpixel area PA.

In the display area DA, the subpixels may be two-dimensionally arranged in the ±x directions and the ±y directions. Arrays of the subpixels, e.g., arrays of the red subpixels R (P-R?), the green subpixels G (P-G?), and the blue subpixels B (P-B?) may define the display area DA.

In an embodiment, the arrays of the subpixels may include multiple columns (or pixel columns) arranged in the ±y directions. Among the subpixels having different colors, two subpixels that emit light having different colors, e.g., the red subpixel P-R and the blue subpixel P-B may be arranged in a same column, and another subpixel, e.g., the green subpixel P-G, may be arranged in another column. The red subpixels P-R and the blue subpixels P-B corresponding to an (i)^{th} (where i is a natural number) column may be arranged apart from each other in an alternate manner in the ±y directions. The green subpixels P-G corresponding to an (i+1)^{th} column may be spaced apart from each other. The arrays of the subpixels may have a structure in which columns of red subpixel P-R and blue subpixels P-B and columns of green subpixels P-G are repeatedly arranged in the ±x directions.

In an embodiment, in a same column (e.g., the (i)^{th} column), a distance between the red subpixels P-R adjacent to each other and a distance between the blue subpixels P-B adjacent to each other may be substantially identical. In a same column (e.g., the (i+1)th column), distances between adjacent green subpixels P-G may be substantially identical.

The red subpixel P-R, the green subpixel P-G, and the blue subpixel P-B may respectively have different areas in a plan view. For example, an area of the blue subpixel P-B may be greater than an area of the red subpixel P-R, and the area of the red subpixel P-R may be greater than an area of the green subpixel P-G. The red subpixel P-R, the green subpixel P-G, and the blue subpixel P-B arranged adjacent to one another may form a virtual triangle. For example, a center of the red subpixel P-R, a center of the green subpixel P-G, and a center of the blue subpixel P-B may be respectively at vertices of the virtual triangle. The virtual triangle may be a right-angled triangle.

Multiple partitions 20 may be arranged in the display area DA. An interval between the partitions 20 adjacent to each other may be constant. The partition 20 may overlap a portion of the subpixel area PA in a plan view. For example, the partition 20 may overlap a portion of each of the red subpixels P-R, the green subpixels P-G, and/or the blue subpixels P-B in a plan view.

Although FIG. 4 illustrates that the partitions 20 are arranged in the ±x directions having a straight stripe shape in which a length in the ±y directions is greater than a length in the ±x directions, the disclosure is not limited thereto, and the shape and arrangement of the partition 20 may be variously modified. For example, the partition 20 may have a curved shape, or a shape of figures, e.g., a square, an oval, and the like. The partitions 20 may also be arranged in the ±y directions. According to an embodiment, the partitions 20 may be arranged at a same interval in the ±y directions having a stripe shape in which the length in the ±x directions is greater than the length in the ±y directions. According to another embodiment, the partitions 20 may each have a rectangular shape having rounded corners, which is similar to the shape of the subpixels (i.e., the red subpixel P-R, the green subpixel P-G, and the blue subpixel P-B), and may be arranged to surround each of the subpixels (e.g., the red subpixel P-R, the green subpixel P-G, and the blue subpixel P-B).

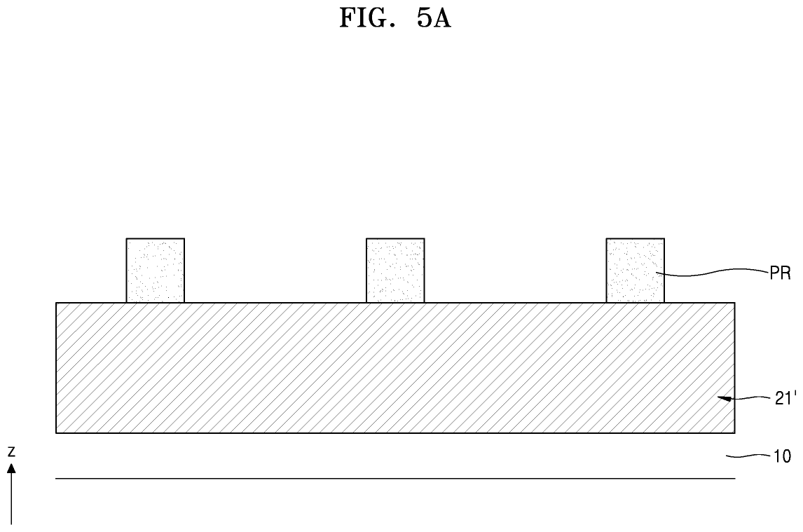

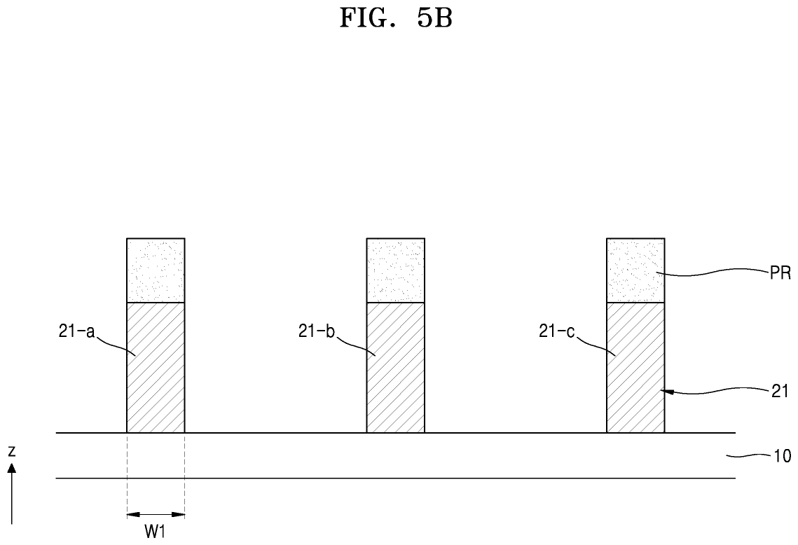

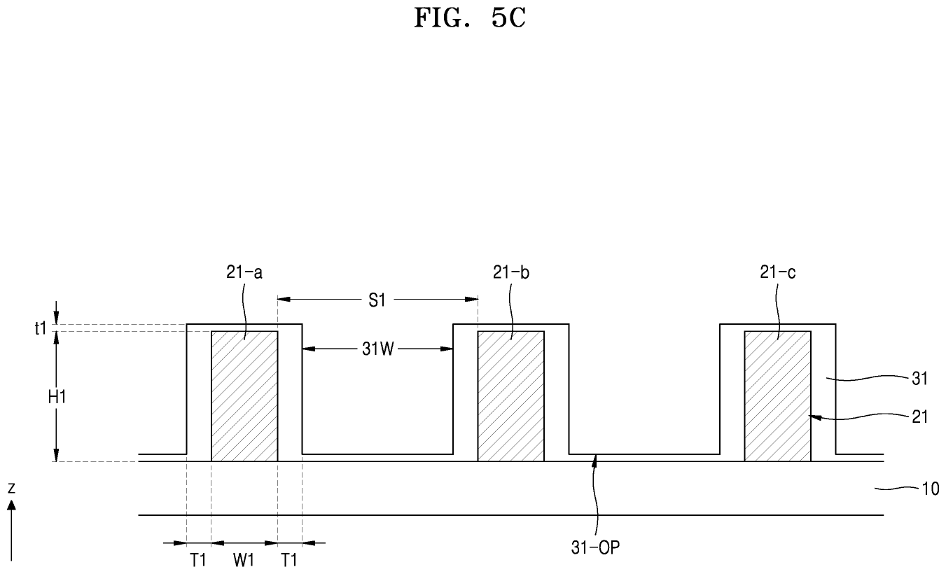

FIGS. 5A to 5C are each a schematic cross-sectional view illustrating a state of a partition structure according to a process of manufacturing thereof, according to an embodiment of the disclosure.

Referring to FIG. 5A, a first partition layer 21′ may be disposed over a display panel 10. The display panel 10 may include the substrate 100 (see FIG. 2), the display element layer 200 (see FIG. 2), the encapsulation layer 300 (see FIG. 2), and/or the input sensing layer 400 described above with reference to FIG. 2.

The first partition layer 21′ may include an inorganic material. For example, the first partition layer 21′ may include molybdenum tantalum oxide (MTO). For example, the first partition layer 21′ may include MTO having a tantalum (Ta) content in a range of about 1 at % to about 15 at %.

A photoresist PR may be formed on the first partition layer 21′. The photoresist PR may include an opening.

Referring to FIG. 5B, multiple first partitions 21 may be formed by etching the first partition layer 21′ using the photoresist PR as a mask. For example, the first partition 21 may include a 1-1 partition 21-a, a 1-2 partition 21-b, and a 1-3 partition 21-c. The 1-1 partition 21-a, the 1-2 partition 21-b, and the 1-3 partition 21-c may be arranged at a uniform interval.

A width W1 of each of the 1-1 partition 21-a, the 1-2 partition 21-b, and the 1-3 partition 21-c may be equal to or greater than about 1.5 μm in a direction, and the structural stability of the 1-1 partition 21-a, the 1-2 partition 21-b, and the 1-3 partition 21-c may be secured. For example, the width W1 of the 1-1 partition 21-a may be about 2.0 μm. Although FIG. 5B illustrates that the widths W1 of the 1-1 partition 21-a, the 1-2 partition 21-b, and the 1-3 partition 21-c are identical, the disclosure is not limited thereto. The widths W1 of the 1-1 partition 21-a, the 1-2 partition 21-b, and the 1-3 partition 21-c may be different from each other. After the first partitions 21 are formed, the photoresist PR may be removed.

Referring to FIG. 5C, the photoresist PR may be removed, and a first auxiliary layer 31 may be formed to cover the 1-1 partition 21-a, the 1-2 partition 21-b, and the 1-3 partition 21-c, and the display panel 10. For example, the first auxiliary layer 31 may be disposed on top surfaces and side surfaces of the 1-1 partition 21-a, the 1-2 partition 21-b, the 1-3 partition 21-c, and a top surface of the display panel 10.

The first auxiliary layer 31 may include openings 31-OP arranged between the 1-1 partition 21-a, the 1-2 partition 21-b, and the 1-3 partition 21-c. The opening 31-OP of the first auxiliary layer 31 may be a blind-hole that does not penetrate the first auxiliary layer 31. A width 31W of the opening 31-OP of the first auxiliary layer 31 may be smaller than a distance S1 between the 1-1 partition 21-a, the 1-2 partition 21-b, and the 1-3 partition 21-c adjacent to each other. For example, the width 31W of the opening 31-OP of the first auxiliary layer 31 may be smaller than the distance S1 between the 1-1 partition 21-a and the 1-2 partition 21-b. According to an embodiment, the distance S1 between the 1-1 partition 21-a and the 1-2 partition 21-b may be equal to a sum of the width 31W of the opening 31-OP and thicknesses T1 of the first auxiliary layer 31 on a side surface of the 1-1 partition 21-a and a side surface of the 1-2 partition 21-b each facing the opening 31-OP of the first auxiliary layer 31 in a direction.

The thickness T1 of the first auxiliary layer 31 arranged on the side surface of each of the 1-1 partition 21-a, the 1-2 partition 21-b, and the 1-3 partition 21-c and a thickness t1 of the first auxiliary layer 31 on the top surface of each of the 1-1 partition 21-a, the 1-2 partition 21-b, and the 1-3 partition 21-c may be different. For example, the thickness T1 of the first auxiliary layer 31 arranged on the side surface of the 1-1 partition 21-a may be greater than the thickness t1 of the first auxiliary layer 31 arranged on the top surface of the 1-1 partition 21-a.

The thickness T1 of the first auxiliary layer 31 on each of the side surfaces of the 1-1 partition 21-a, the partition 21-b, and the 1-3 partition 21-c may be less than or equal to about 1.0 μm. For example, the thickness T1 of the first auxiliary layer 31 on each of the side surfaces of the 1-1 partition 21-a, the 1-2 partition 21-b, and the 1-3 partition 21c may be about 0.8 μm. In case that the thickness T1 of the first auxiliary layer 31 on each of the side surfaces of the 1-1 partition 21-a, the 1-2 partition 21-b, and the 1-3 partition 21-c is less than or equal to about 1.0 μm, the structure of the 1-1 partition 21-a, the 1-2 partition 21-b, and the 1-3 partition 21-c may be secured, and a process margin may be secured as a second partition to be described later is arranged.

A height H1 of the 1-1 partition 21-a, the 1-2 partition 21-b, and the 1-3 partition 21-c may be greater than the distance S1 between the 1-1 partition 21-a, the 1-2 partition 21-b, and the 1-3 partition 21-c adjacent to each other. For example, the height H1 of the 1-1 partition 21-a may be greater than the distance S1 between the 1-1 partition 21-a and the 1-2 partition 21-b. According to an embodiment, the height H1 of the 1-1 partition 21-a may be about 3.0 μm, and the distance S1 between the 1-1 partition 21-a and the 1-2 partition 21-b may be about 2.0 μm. The 1-1 partition 21-a, the 1-2 partition 21-b, and the 1-3 partition 21-c may each effectively absorb emitted light that is not perpendicular to the display panel 10 from among light emitted between the 1-1 partition 21-a, the 1-2 partition 21-b, and the 1-3 partition 21-c.

The first auxiliary layer 31 may include a transparent material. For example, the first auxiliary layer 31 may include silicon oxide (SiO₂), silicon oxynitride (SiON), silicon nitride (SiNₓ), or the like.

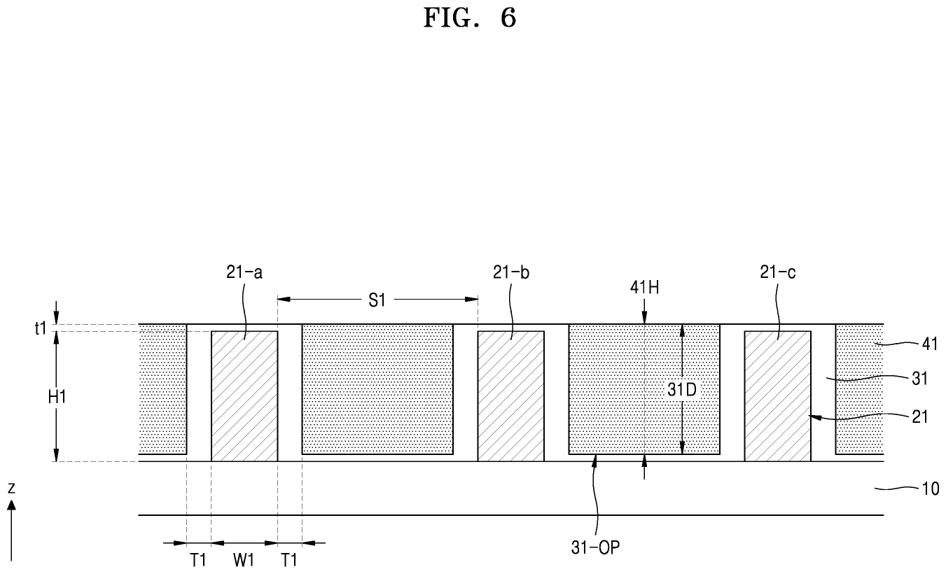

FIG. 6 is a schematic cross-sectional view of a partition structure according to an embodiment of the disclosure.

Referring to FIG. 6, the partition structure may further include a first stable layer 41.

At least a portion of the first stable layer 41 may be arranged in the opening 31-OP of the first auxiliary layer 31. Although FIG. 6 illustrates that a depth 31D of the opening 31-OP of the first auxiliary layer 31 is identical to a height 41H of the first stable layer 41, the disclosure is not limited thereto. A top surface of the first stable layer 41 may protrude or recess than a top surface of the first auxiliary layer 31.

The first stable layer 41 may include a transparent material. For example, the first stable layer 41 may include polyimide (PI).

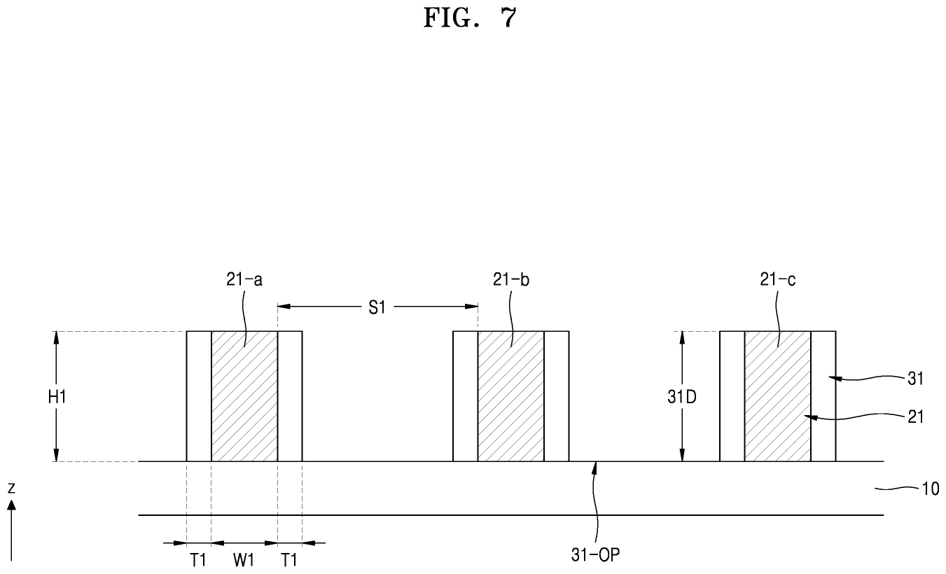

FIG. 7 is a schematic cross-sectional view of a partition structure according to an embodiment of the disclosure.

Referring to FIG. 7, other features of the partition structure except the structure of the first auxiliary layer 31 are the same as the embodiment of FIG. 5C, and therefore, the description of the partition structure of FIG. 7 will be replaced with the description with reference to FIG. 5C, and differences between the partition structure shown in FIGS. 5A to 5C and the partition structure shown in FIG. 7 will be described.

A portion of the first auxiliary layer 31 arranged on the top surface of the 1-1 partition 21-a, the 1-2 partition 21-b, and the 1-3 partition 21-c and a portion of the first auxiliary layer 31 arranged on the top surface of the display panel 10 may be etched. In other words, the first auxiliary layer 31 may be arranged only on the side surface of each of the 1-1 partition 21-a, the 1-2 partition 21-b, and the 1-3 partition 21-c. The top surfaces of the 1-1 partition 21-a, the 1-2 partition 21-b, and the 1-3 partition 21-c and the top surface of the display panel 10 may be exposed.

The depth 31D of the opening 31-OP of the first auxiliary layer 31 may be identical to the height H1 of the 1-1 partition 21-a, the 1-2 partition 21-b, and the 1-3 partition 21-c. In other words, the opening 31-OP of the first auxiliary layer 31 may be

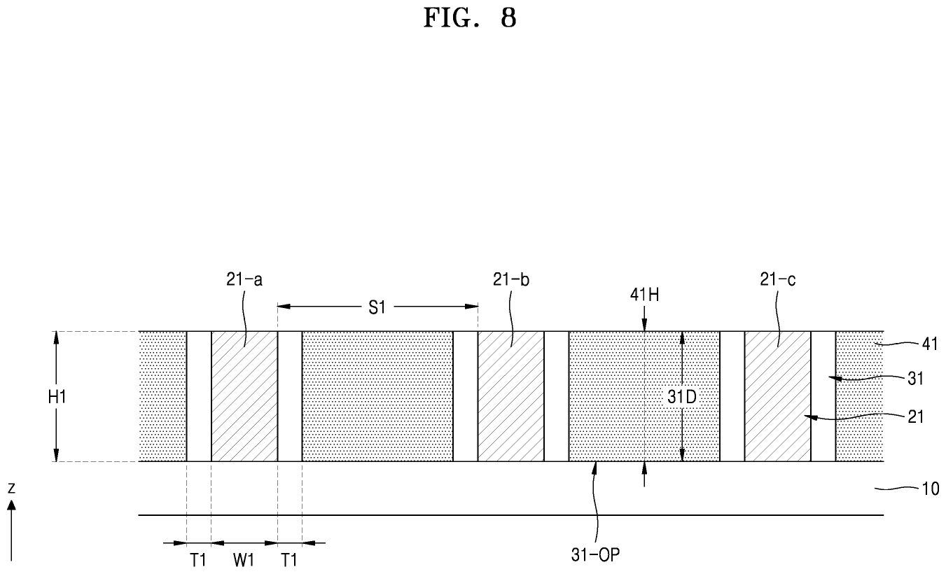

FIG. 8 is a schematic cross-sectional view of a partition structure according to an embodiment of the disclosure.

Referring to FIG. 8, the partition structure may further include the first stable layer 41 in addition to the embodiment of the partition structure described with reference to FIG. 7. Features of the first stable layer 41 are identical to the features described with reference to FIG. 6, and thus will not be described again.

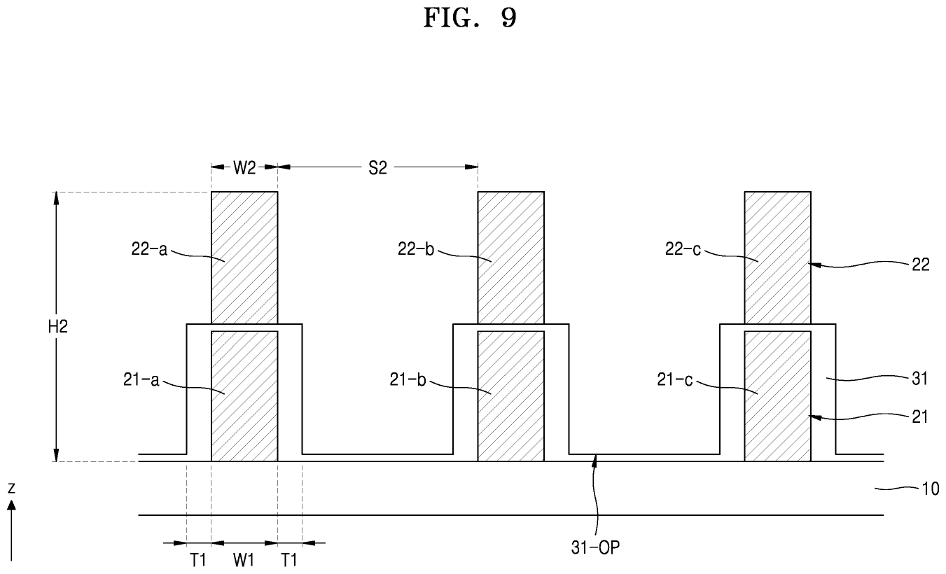

FIG. 9 is a schematic cross-sectional view of a partition structure according to an embodiment of the disclosure.

Referring to FIG. 9, the partition structure may further include a second partition 22 in addition to the embodiment of the partition structure shown in FIG. 5C. The second partition 22 may include a 2-1 partition 22-a, a 2-2 partition 22-b, and a 2-3 partition 22-c.

At least portions of the 2-1 partition 22-a, the 2-2 partition 22-b, and the 2-3 partition 22-c may respectively overlap portions of the 1-1 partition 21-a, the 1-2 partition 21-b, and the 1-3 partition 21-c in a plan view and may be disposed over the first auxiliary layer 31. Although FIGS. 9 illustrates that the 2-1 partition 22-a, the 2-2 partition 22-b, and the 2-3 partition 22-c completely overlap the 1-1 partition 21-a, the 1-2 partition 21-b, and the 1-3 partition 21-c in a thickness direction of the display panel 10, respectively, the disclosure is not limited thereto. According to another embodiment, each of the 2-1 partition 22-a, the 2-2 partition 22-b, and the 2-3 partition 22-c may be offset left or right from each of the 1-1 partition 21-a, the 1-2 partition 21-b, and the 1-3 partition 21-c, and may only partially overlap the 1-1 partition 21-a, the 1-2 partition 21-b, and the 1-3 partition 21-c in the thickness direction.

A width W2 of each of the 2-1 partition 22-a, the 2-2 partition 22-b, and the 2-3 partition 22-c may be equal to or greater than about 1.5 μm in a direction. For example, the width W2 of each of the 2-1 partition 22-a, the 2-2 partition 22-b, and the 2-3 partition 22-c may be about 2.0 μm. According to an embodiment, the width W2 of each of the 2-1 partition 22-a, the 2-2 partition 22-b, and the 2-3 partition 22-c may be identical to the width W1 of each of the 1-1 partition 21-a, the 1-2 partition 21-b, and the 1-3 partition 21-c. Although FIG. 9 illustrates that the width W2 of the 2-1 partition 22-a, the 2-2 partition 22-b, and the 2-3 partition 22-c are identical, the disclosure is not limited thereto. The widths W2 of the 2-1 partition 22-a l , the 2-2 partition 22-b, and the 2-3 partition 22-c may be different from each other.

The 2-1 partition 22-a, the 2-2 partition 22-b, and the 2-3 partition 22-c may each include an inorganic material. For example, the 2-1 partition 22-a, the 2-2 partition 22-a, and the 2-3 partition 22-c may each include molybdenum tantalum oxide (MTO). For example, the 2-1 partition 22-a, the 2-2 partition 22-b, and the 2-3 partition 22-c may each include MTO having a Ta content in a range of about 1 at % to about 15 at %. According to an embodiment, the 2-1 partition 22-a, the 2-2 partition 22-b, and the 2-3 partition 22-c and the 1-1 partition 21-a, the 1-2 partition 21-b, and the 1-3 partition 21-c may include a same material.

A height H2 of each of the 2-1 partition 22-a, the 2-2 partition 22-b, and the 2-3 partition 22-c measured from the top surface of the display panel 10 to a top surface of each of the 2-1 partition 22-a, the 2-2 partition 22-b, and the 2-3 partition 22-c may be greater than a distance S2 between the 2-1 partition 22-a, the 2-2 partition 22-b, and the 2-3 partition 22-c. For example, the height H2 of the 2-1 partition 22-a measured from the top surface of the display panel 10 to the top surface of the 2-1 partition 22-a may be greater than the distance S2 between the 2-1 partition 22-a and the 2-2 partition 22-b. According to an embodiment, the height H2 of the 2-1 partition 22-a measured from the top surface of the display panel 10 to the top surface of the 2-1 partition 22-a may be about 6.0 μm, and the distance S2 between the 2-1 partition 22-a and the 2-2 partition 22-b may be about 4.0 μm.

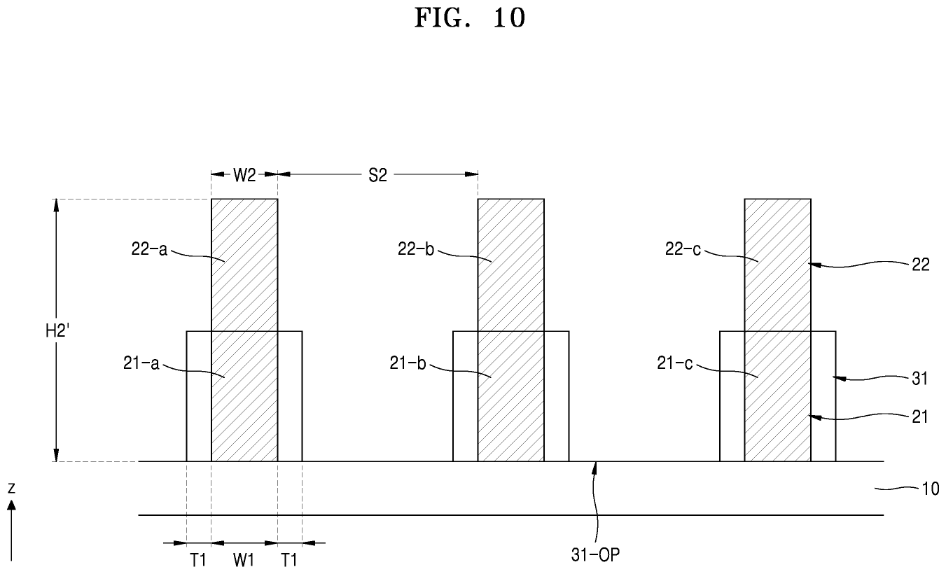

FIG. 10 is a schematic cross-sectional view of a partition structure according to an embodiment of the disclosure.

The embodiment shown in FIG. 10 is the same as the embodiment of FIG. 9, therefore, the description of the partition structure will be replaced with the description with reference to FIG. 9, and differences between the partition structures of FIGS. 9 and 10 will be described. Referring to FIG. 10, the partition structure may further include the second partition 22 in addition to the embodiment of the partition structure shown in FIG. 7. The second partition 22 may include a 2-1 partition 22-a, a 2-2 partition 22-b, and a 2-3 partition 22-c.

A height H2′ of each of the 2-1 partition 22-a, the 2-2 partition 22-b, and the 2-3 partition 22-c measured from the top surface of the display panel 10 to the top surface of the 2-1 partition 22-a, the 2-2 partition 22-b, and the 2-3 partition 22-c may be greater than the distance S2 between the 2-1 partition 22-a, the 2-2 partition 22-b, and the 2-3 partition 22-c. For example, the height H2′ of the 2-1 partition 22-a measured from the top surface of the display panel 10 to the top surface of the 2-1 partition 22-a may be greater than the distance S2 between the 2-1 partition 22-a and the 2-2 partition 22-b. According to an embodiment, the height H2′ of the 2-1 partition 22-a measured from the top surface of the display panel 10 to the top surface of the 2-1 partition 22-a may be about 5.5 μm, and the distance S2 between the 2-1 partition 22-a and the 2-2 partition 22-b may be about 3.5 μm.

The 2-1 partition 22-a, the 2-2 partition 22-b, and the 2-3 partition 22-c may directly contact the 1-1 partition 21-a, the 1-2 partition 21-b, and the 1-3 partition 21-c, respectively. For example, bottom surfaces of the 2-1 partition 22-a, the 2-2 partition 22-b, and the 2-3 partition 22-c may directly contact the top surfaces of the 1-1 partition 21-a, the 1-2 partition 21-b, and the 1-3 partition 21-c, respectively. For example, the bottom surface of the 2-1 partition 22-a may directly contact the top surface of the 1-1 partition 21-a, the bottom surface of the 2-2 partition 22-b may directly contact the top surface of the 1-2 partition 21-b, and the bottom surface of the 2-3 partition 22-c may directly contact the top surface of the 1-3 partition 21-c, respectively.

Although not shown in FIGS. 9 and 10, the first stable layer 41 may be arranged in the opening 31-OP of the first auxiliary layer 31. Features of the first stable layer 41 may be identical to the description with reference to FIG. 6.

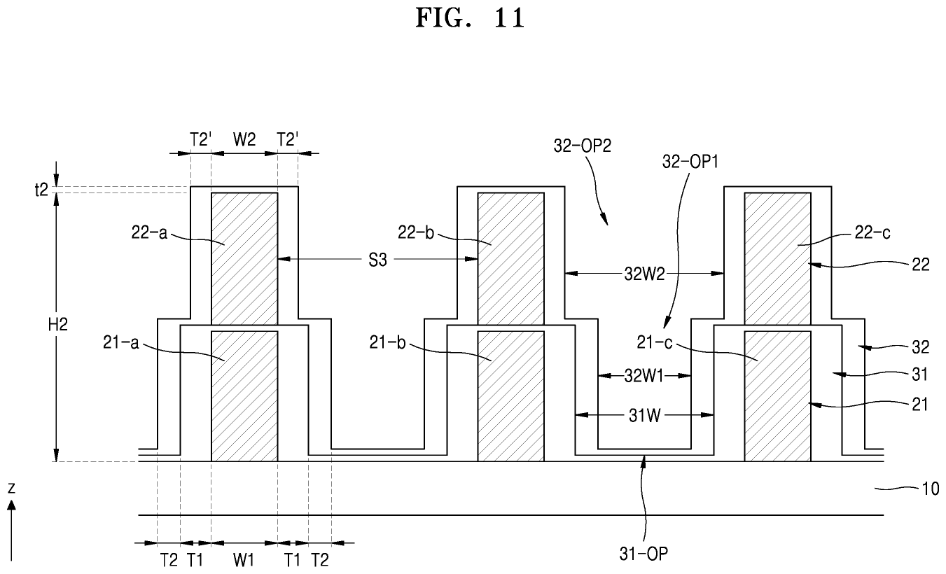

FIG. 11 is a schematic cross-sectional view of a partition structure according to an embodiment of the disclosure.

Referring to FIG. 11, the partition structure may further include a second auxiliary layer 32 in addition to the embodiment of the partition structure shown in FIG. 9. The second auxiliary layer 32 may cover the 2-1 partition 22-a, the 2-2 partition 22-b, the 2-3 partition 22-c, and the first auxiliary layer 31. For example, the second auxiliary layer 32 may be disposed on top surfaces and side surfaces of the 2-1 partition 22-a, the 2-2 partition 22-b, and the 2-3 partition 22-c and the first auxiliary layer 31.

The second auxiliary layer 32 may include a first opening 32-OP1 arranged between the 1-1 partition 21-a, the 1-2 partition 21-b, and the 1-3 partition 21-c. The first opening 32-OP1 of the second auxiliary layer 32 may be a blind-hole that does not penetrate the second auxiliary layer 32. A width 32W1 of the first opening 32-OP1 of the second auxiliary layer 32 may be less than a distance S3 between the 1-1 partition 21-a, the 1-2 partition 21-b, and the 1-3 partition 21-c adjacent to each other and the width 31W of the opening 31-OP of the first auxiliary layer 31 in a direction. For example, the width 32W1 of the first opening 32-OP1 of the second auxiliary layer 32 may be less than the distance S3 between the 1-1 partition 21-a and the 1-2 partition 21-b.

The second auxiliary layer 32 may include second openings 32-OP2 arranged between the 2-1 partition 22-a, the 2-2 partition 22-b, and the 2-3 partition 22-c. The second opening 32-OP2 of the second auxiliary layer 32 may be a blind-hole that does not penetrate the second auxiliary layer 32. A width 32W2 of the second opening 32-OP2 of the second auxiliary layer 32 may be less than the distance S3 between the 2-1 partition 22-a, the 2-2 partition 22-b, and the 2-3 partition 22-c adjacent to each other in a direction. For example, the width 32W2 of the second opening 32-OP2 of the second auxiliary layer 32 may be less than the distance S3 between the 2-1 partition 22-a and the 2-2 partition 22-b. The width 32W2 of the second opening 32-OP2 of the second auxiliary layer 32 may be greater than the width 32W1 of the first opening 32-OP1 of the second auxiliary layer 32.

A thickness T2′ of the second auxiliary layer 32 arranged on side surfaces of the 2-1 partition 22-a, the 2-2 partition 22-b, and the 2-3 partition 22-c and a thickness t2 of the second auxiliary layer 32 arranged on the top surfaces of the 2-1 partition 22-a, the 2-2 partition 22-b, and the 2-3 partition 22-c may be different. For example, the thickness T2′ of the second auxiliary layer 32 arranged on the side surface of the 2-partition 22-a may be greater than the thickness t2 of the second auxiliary layer 32 arranged on the top surface of the 2-1 partition 22-a.

The thickness T2 of the second auxiliary layer 32 arranged on the side surfaces of the 1-1 partition 21-a, the 1-2 partition 21-b, and the 1-3 partition 21-c and the thickness T2 ′ of the second auxiliary layer 32 arranged on the side surfaces of the 2-1 partition 22-a, the 2-2 partition 22-b, and the 2-3 partition 22-c may be less than or equal to about 1.0 μm. The thickness T2 of the second auxiliary layer 32 arranged on the side surfaces of the 1-1 partition 21-a, the 1-2 partition 21-b, and the 1-3 partition 21-c and the thickness T2′ of the second auxiliary layer 32 arranged on the side surfaces of the 2-1 partition 22-a, the 2-2 partition 22-b, and the 2-3 partition 22-b may be less than the thickness T1 of the first auxiliary layer 31 arranged on the side surfaces of the 1-1 partition 21-a, the 1-2 partition 21-b, and the 1-3 partition 21-c. For example, the thickness T1 of the first auxiliary layer 31 disposed on the side surfaces of the 1-1 partition 21-a, the 1-2 partition 21-b, and the 1-3 partition 21-c may be about 0.8 μm, and the thickness T2 of the second auxiliary layer 32 disposed on the side surfaces of the 1-1 partition 21-a, the 1-2 partition 21-b, and the 1-3 partition 21-c and the thickness T2′ of the second auxiliary layer 32 disposed on the side surfaces of the 2-1 partition 22-a, the 2-2 partition 22-b, and the 2-3 partition 22-c may be 0.6 μm.

Although FIG. 11 illustrates that the thickness T2 of the second auxiliary layer 32 disposed on the side surfaces of the 1-1 partition 21-a, the 1-2 partition 21-b, and the 1-3 partition 21c is identical to the thickness T2′ of the second auxiliary layer 32 disposed on the side surfaces of the 2-1 partition 22-a, the 2-2 partition 22-b, and the 2-3 partition 22-c, the disclosure is not limited thereto. According to another embodiment, the thickness T2 of the second auxiliary layer 32 disposed on the side surfaces of the 1-1 partition 21-a, the 1-2 partition 21-b, and the 1-3 partition 21-c and the thickness T2′ of the second auxiliary layer 32 arranged on the side surfaces of the 2-1 partition 22-a, the 2-2 partition 22-b, and the 2-3 partition 22-c may be different.

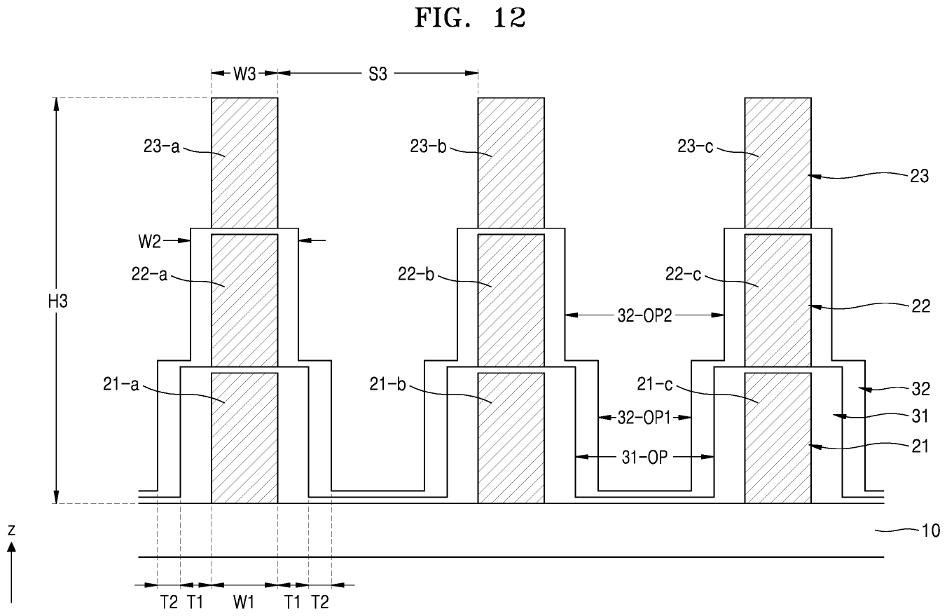

FIG. 12 is a schematic cross-sectional view of a partition structure according to an embodiment of the disclosure.

Referring to FIG. 12, the partition structure may further include a third partition 23 in addition to the embodiment of the partition structure shown in FIG. 11. The third partition 23 may include a 3-1 partition 23-a, a 3-2 partition 23-b, and a 3-3 partition 23-c.

At least portions of the 3-1 partition 23-a, the 3-2 partition 23-b, and the 3-3 partition 23-c may overlap at least portions of the 2-1 partition 22-a, the 2-2 partition 22-b, and the 2-3 partition 22-c in a plan view, and may be disposed on the second auxiliary layer 32. Although FIG. 12 illustrates that the 3-1 partition 23-a, the 3-2 partition 23-b, and the 3-3 partition 23-ccompletely overlap the 2-1 partition 22-a, the 2-2 partition 22-b, and the 2-3 partition 23-b, respectively, the disclosure is not limited thereto. According to another embodiment, each of the 3-1 partition 23-a, the 3-2 partition 23-b, and the 3-3 partition 23-b may be offset left or right from each of the 2-1 partition 22-a, the 2-2 partition 22-b, and the 2-3 partition 22-c, and may only partially overlap the 3-1 partition 23-a, the 3-2 partition 23-b, and the 3-3 partition 23-c in a plan view.

A width W3 of each of the 3-1 partition 23-a, the 3-2 partition 23-b, and the 3-3 partition 23-c may be equal to or greater than about 1.5 μm in a direction. For example, the width W3 of each of the 3-1 partition 23-a, the 3-2 partition 23-b, and the 3-3 partition 23-c may be about 2.0 μm. The width W3 of the 3-1 partition 23-a, the 3-2 partition 23-b, and the 3-3 partition 23-c may be identical to the width W2 of the 2-1 partition 22-a, the 2-2 partition 22-b, and the 2-3 partition 22-c and the width W1 of the 1-1 partition 21-a, the 1-2 partition 21-b, and the 1-3 partition 21-c. For example, the width W1 of the 3-1 partition 23-a may be identical to the width W1 of the 2-1 partition 22-a and the width W1 of the 1-1 partition 21-a.

Although FIG. 12 illustrates that the widths W1 of the 3-1 partition 23-a, the 3-2 partition 23-b, and the 3-3 partition 23-b are identical, the disclosure is not limited thereto. In another embodiment, the widths W1 of the 3-1 partition 23-a, the 3-2 partition 23-b, and the 3-3 partition 23-c may be different.

The 3-1 partition 23-a, the 3-2 partition 23-b, and the 3-3 partition 23-b may each include an inorganic material. For example, the 3-1 partition 23-a, the 3-2 partition 23-b, and the 3-3 partition 23-c may each include MTO. For example, the 3-1 partition 23-a, the 3-2 partition 23-b, and the 3-3 partition 23-c may each include MTO having a Ta content in a range of about 1 at % to 15 at %. According to an embodiment, the 3-1 partition 23-a, the 3-2 partition 23-b, and the 3-3 partition 23-c and the 2-1 partition 22-a, the 2-2 partition 22-b, and the 2-3 partition 22-c may include a same material.

A height H3 of the 3-1 partition 23-a, the 3-2 partition 23-b, and the 3-3 partition 23-c measured from the top surface of the display panel 10 to top surfaces of the 3-1 partition 23-a, the 3-2 partition 23-b, and the 3-3 partition 23-c may be greater than the distance S3 between the 3-1 partition 23-a, the 3-2 partition 23-b, and the 3-3 partition 23-c. For example, the height H3 of the 3-1 partition 23-a measured from the top surface of the display panel 10 to the top surfaces of the 3-1 partition 23-a may be greater than the distance S3 between the 3-1 partition 23-a and the 3-2 partition 23-b. According to an embodiment, the height H3 of the 3-1 partition 23-a measured from the top surface of the display panel 10 to the top surface of the 3-1 partition 23-a may be about 9.0 μm, and the distance S3 between the 3-1 partition 23-a and the 3-2 partition 23-b may be about 6.0 μm.

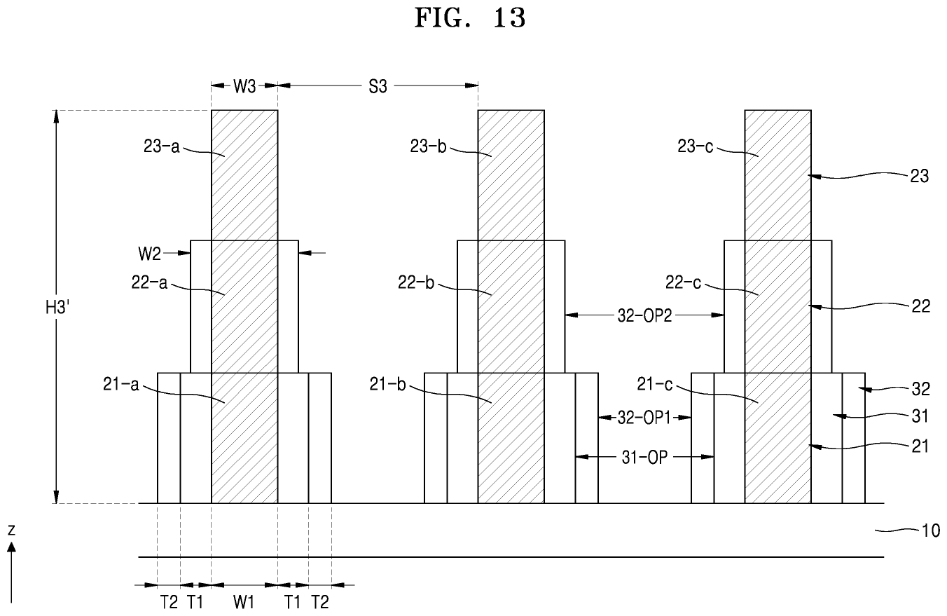

FIG. 13 is a schematic cross-sectional view of a partition structure according to an embodiment of the disclosure.

Except features to be described hereinafter, other features of the embodiment shown in FIG. 13 is the same as the features described with reference to FIG. 12, therefore, the description of the partition structure will be replaced with the description with reference to FIG. 12, and differences between the partition structures respectively shown in FIGS. 12 and 13 will be described.

Referring to FIG. 13, a height H3′ of the 3-1 partition 23-a, the 3-2 partition 23-b, and the 3-3 partition 23-c measured from the top surface of the display panel 10 to the top surfaces of the 3-1 partition 23-a, the 3-2 partition 23-b, and the 3-3 partition 23-c may be greater than the distance S3 between the 3-1 partition 23-a, the 3-2 partition 23-b, and the 3-3 partition 23-c. For example, a height H3′ of the 3-1 partition 23-a measured from the top surface of the display panel 10 to the top surface of the 3-1 partition 23-a may be greater than the distance S3 between the 3-1 partition 23-a and the 3-2 partition 23-b. According to an embodiment, the height H3 of the 3-1 partition 23-a measured from the top surface of the display panel 10 to the top surface of the 3-1 partition 23-a may be about 8.0 μm, and the distance S3 between the 3-1 partition 23-a and the 3-2 partition 23-b may be about 5.0 μm.

The 3-1 partition 23-a, the 3-2 partition 23-b, and the 3-3 partition 23-c may directly contact the 2-1 partition 22-a, the 2-2 partition 22-b, and the 2-3 partition 22-c, respectively. For example, bottom surfaces of the 3-1 partition 23-a, the 3-2 partition 23-b, and the 3-3 partition 23-c may directly contact the top surfaces of the 2-1 partition 22-a, the 2-2 partition 22-b, and the 2-3 partition 22-c, respectively. For example, the bottom surface of the 3-1 partition 23-a may directly contact the top surface of the 2-1 partition 22-a, the bottom surface of the 3-2 partition 23-b may directly contact the top surface of the 2-2 partition 22-b, and the bottom surface of the 3-3 partition 23-c may directly contact the top surface of the 2-3 partition 22-c.

Although not shown in FIGS. 11 to 13, the first stable layer 41 may be arranged in the first opening 32-OP1 of the second auxiliary layer 32, and a second stable layer may be arranged in the second opening 32-OP2 of the second auxiliary layer 32. Features of the first stable layer and the second stable layer may be identical to the features of the first stable 41 (see FIG. 6) described above with reference to FIG. 6.

As described above, the disclosure describes the 1-1 partition to 1-3 partition, the 2-1 partition to 2-3 partition, and the 3-1 partition to 3-3 partition. However, numbers of the partitions are not limited thereto. In another embodiment, the display apparatus 1 according to an embodiment may include a greater number of partitions. For example, the display apparatus 1 may include 1-1 to 1-10 partitions, or may include 1-1 to 1-5 partitions, 2-1 to 2-5 partitions, 3-1 to 3-5 partitions, and 4-1 to 4-5 partitions.

According to an embodiment of the disclosure as described above, a display apparatus that only filters emitted light in a certain direction from among emitted light generated in a display panel may be implemented. However, the scope of the disclosure is not limited thereto.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
a display panel comprising a display area;
a plurality of first partitions disposed on the display panel in the display area; and
a first auxiliary layer arranged on at least a portion of outer surfaces of the plurality of first partitions and comprising an opening arranged between adjacent ones of the plurality of first partitions.

2. The display apparatus of claim 1, wherein a height of at least one of the plurality of first partitions measured from a top surface of the display panel to a top surface of the at least one of the plurality of first partitions is greater than a distance between adjacent ones of the plurality of first partitions.

3. The display apparatus of claim 1, wherein at least one of the plurality of first partitions comprises an inorganic material.

4. The display apparatus of claim 3, wherein the at least one of the plurality of first partitions comprises molybdenum tantalum oxide (MoTaOₓ, MTO).

5. The display apparatus of claim 1, wherein the first auxiliary layer covers the plurality of first partitions and the display panel.

6. The display apparatus of claim 1, wherein the first auxiliary layer comprises a transparent material.

7. The display apparatus of claim 1, further comprising:
a first stable layer at least partially arranged in the opening of the first auxiliary layer.

8. The display apparatus of claim 7, wherein the first stable layer comprises a transparent material.

9. The display apparatus of claim 1, further comprising:
a second partition arranged on and overlapping at least one of the plurality of first partitions in a plan view.

10. The display apparatus of claim 9, wherein a height of the second partition measured from a top surface of the display panel to a top surface of the second partition is greater than a distance between adjacent ones of the plurality of first partitions.

11. The display apparatus of claim 9, wherein the at least one of the plurality of first partitions directly contacts the second partition.

12. The display apparatus of claim 9, wherein the second partition comprises an inorganic material.

13. The display apparatus of claim 9, further comprising:
a plurality of second partitions, and
a second auxiliary layer arranged on at least a portion of outer surfaces of the plurality of second partitions and comprising an opening arranged between adjacent ones of the plurality of second partitions.

14. The display apparatus of claim 9, further comprising:
a third partition arranged on the second partition and overlapping the second partition in a plan view.

15. The display apparatus of claim 14, wherein a height of the third partition measured from a top surface of the display panel to a top surface of the third partition is greater than a distance between adjacent ones of the plurality of first partitions.

16. The display apparatus of claim 14, wherein the second partition directly contacts the third partition.

17. The display apparatus of claim 14, wherein the third partition comprises an inorganic material.

18. A display apparatus comprising:
a display panel comprising a display area including a plurality of subpixels and a non-display area;
a plurality of first partitions disposed on the display panel in the display area and overlapping at least one of the plurality of subpixels in a plan view; and
a first auxiliary layer arranged on at least a portion of outer surfaces of the plurality of first partitions and comprising an opening arranged between adjacent ones of the plurality of first partitions.

19. The display apparatus of claim 18, wherein the first auxiliary layer covers at least one of the plurality of first partitions.

20. The display apparatus of claim 18, wherein the first auxiliary layer is arranged on side surfaces of the plurality of first partitions.

21. The display apparatus of claim 18, further comprising:
a first stable layer at least partially arranged in the opening.

22. The display apparatus of claim 18, further comprising:
a second partition arranged on and overlapping at least one of the plurality of first partitions in a plan view.

23. The display apparatus of claim 22, wherein the at least one of the plurality of first partitions directly contacts the second partition.
